(19) United States
(12) Patent Application Publication
(10) Pub. No.: US 2011/0151607 A1
(43) Pub. Date: Jun. 23, 2011

(54) METHOD FOR MANUFACTURING A METAL AND DIELECTRIC NANOSTRUCTURES ELECTRODE FOR COLORED FILTERING IN AN OLED AND METHOD FOR MANUFACTURING AN OLED

(75) Inventors: Stefan Landis, Voiron (FR); Nicolas Chaix, Saint-Martin D'Uriage (FR); Valentina Ivanova-Hristova, Grenoble (FR); Carole Pernel, Saint-Egreve (FR)

(73) Assignee: COMMISSARIAT A L'ENERGIE ATOMIQUE ET AUX ENERGIES ALTERNATIVES, Paris (FR)

(21) Appl. No.: 12/976,265

(22) Filed: Dec. 22, 2010

(30) Foreign Application Priority Data
Dec. 23, 2009 (FR) 09 59499

(51) Int. Cl. H01L 51/56

(52) U.S. Cl. 438/46; 257/E51.019

(57) ABSTRACT

A method for manufacturing an OLED and an electrode for an OLED, said electrode comprising a surface comprising a first dielectric nanostructuration and a second metal nanostructuration, on a substrate, wherein the following successive steps are carried out:
a) a metal layer is deposited on a planar surface of a substrate;
b) on the metal layer, a dielectric layer comprising said first dielectric nanostructuration which includes cavities which extend from the upper surface of the dielectric layer as far as the upper surface of the metal layer, is prepared;
c) the cavities of the first dielectric nanostructuration are at least partially filled with a metal, whereby the second metal nanostructuration is obtained.

### TECHNICAL FIELD

The invention relates to a method for manufacturing an electrode, preferably an anode, comprising a surface with metal and dielectric nanostructures for colored filtering and enhancement of light extraction in an Organic Light-Emitting Diode (OLED).

The invention further relates to a method for manufacturing an organic light-emitting diode OLED comprising at least one step for manufacturing an electrode comprising a surface with metal and dielectric nanostructures with the above method.

The technical field of the invention may be defined as that of organic light-emitting diodes and more particularly as that of organic light-emitting diodes for which one electrode, preferably the anode, is provided with metal nanostructurations with view to colored filtering and enhancement of the light extraction.

### STATE OF THE PRIOR ART

Organic light-emitting diodes OLED are new generation diodes and are a very promising technology for displays, such as television screens and computer screens etc., and for lighting, by their low electricity consumption.

In a simplified way, an organic light-emitting diode comprises a substrate or a superstrate, an anode, a cathode and emitting organic layer(s) provided between the anode and the cathode.

The electrode in contact with the substrate is generally the anode.

Light emission may occur on the side of the anode or else on the side of the cathode.

The electrode through which light emission is achieved, is transparent to this light.

A typical OLED, in which light emission is achieved on the side of the anode and of the substrate thus comprises for example a glass substrate (which may then be called a superstrate), a transparent anode in Indium Tin Oxide (ITO) for example, a stack of organic layers, and a metal mirror acting as a cathode.

In FIG. 1, another typical OLED is illustrated, in which light emission is achieved on the side of the cathode (3) i.e. on the side opposite to the anode (2) and to the substrate (1).

This diode comprises one or more thin organic emitting layer(s) (4), for example three thin organic emitting layers which respectively emit in the red, green and blue, which are surrounded on the one hand by a metal anode (2) for example in aluminium or silver in contact with the substrate (1), and by a transparent cathode (3) on the other hand, formed for example by ITO or by a thin silver layer.

P-doped (5) or N-doped (6) dielectric layers also called electron or hole injection layers are generally added between the electrodes (2,3) and the emitting layers (4) in order to improve injection of charges (electrons (7) and holes (8)) in the organic emitting layers (4). Electron blocking (9) and hole blocking (10) layers may also be provided.

In an OLED and notably in an OLED as the one illustrated in FIG. 1, light is emitted in the organic layers in all directions.

Only a fraction (about 20%) of the emitted photons is actually extracted from the diode (11) and 80% of the photons and of the light are therefore lost (12) in the different electromagnetic modes relating to the metal and dielectric layers.

These lost photons captured by the structure are possibly absorbed by the Joule effect or re-emitted on the edges of the diode. In all cases, these photons do not participate in the<<useful light>>of the diode.

It is therefore crucial to improve the extraction of the lost photons in order to convert them into useful photons so as to increase the optical yield.

In order to recover part of the energy lost in the plasmons or guided modes, the use of periodic lattices was proposed for example in the document of W. L. BARNES, Journal of Lightwave technology, Vol. 17, No. 11, November 1999, pages 2170-2182 [1].

These lattices may be one-dimensional, such as line lattices sensitive to polarization of the emitters, or two-dimensional, such as square, triangular, Archimedean lattices, or lattices of more complex geometry.

In FIG. 2, an OLED has been illustrated in a simplified way with an anode (21), organic layers (22) and a cathode (23) which are provided with periodic structurations (24) formed by patterns (25). These periodic structurations have a period P and a height h.

However, a poorly controlled structuration may cause both electrodes to be short-circuited, making the OLED stack unusable. Further, technology which allows structuration of the OLED should necessarily be compatible with the manufacturing methods used in microelectronics.

The emitting organic layers of OLEDs are further very sensitive to air, water and to mechanical stresses.

Experiment shows that the emitting molecules of these layers poorly withstand all the treatments occurring<<a posteriori>>after globally making the diodes. This is why the structuration of the OLED is advantageously printed, directly made on the substrate as this is described in the document of D. K. GILFORD et D. G. HALL, Applied Physics Letters, Volume 81, Number 23, Dec. 2, 2002, pages 4315-4317 [2] and in the document of D. K. GILFORD et D. G. HALL, Applied Physics Letters, Volume 80, Number 20, May 20, 2002, pages 3679-3681 [3]. As the deposits of different metal and organic layers of the diode are compliant, the pattern of the lattice is reproduced on the whole of the diode.

More specifically, the document of D. K. GILFORD and D. G. HALL, Applied physics Letters, Volume 81, Number 23, Dec. 2, 2002, pages 4315-4317 [2], describes the manufacturing of an OLED, during which a photosensitive resin layer with a thickness of 80 mm is first of all spin-coated on a silicon substrate.

This photosensitive resin layer is then holographically printed and treated in order to form a lattice having a surface relief with a period of 550 nm and a peak-valley amplitude of about 60 nm.

On the photosensitive resin layer, five layers are successively deposited by deposition in vacuo, i.e. a gold layer, an NPB layer, a layer of tris(8-hydroquinoline) aluminium (Alq₃), an aluminium layer and a silver layer. The gold layer forms the anode of the device while the Al/Ag layers form the cathode.

The layers deposited on the resin, reproduce the underlying lattice of the latter, and thereby form a periodic undulation in the whole of the structure.

In the document of D. K. GILFORD and D. G. HALL, Applied Physics Letters, Volume 80, Number 20, May 20, 2002, pages 3679-3681 [3], glass slides are first of all coated with a thin layer (200 nm) of photosensitive resin.

The photosensitive resin films are then exposed to holographic interference fringes and developed in order to form a lattice having surface relief with periods from 535 to 610 nm and peak-valley amplitudes of about 100 nm.

The samples are then coated in vacuo with a film of tris(8-hydroquinoline) aluminium (Alq₃) with a thickness of 200 nm, and then with a silver layer with a thickness of 50 nm.

The deposited layers reproduce the profile of the underlying resin surface and thereby form undulations in the whole of the structure.

Moreover the document of K. ISHIHARA, Applied Physics Letters 90, 111114 (2007) [4] describes the manufacturing of an OLED with a layer of two-dimensional photonic crystals. Two-dimensional periodic undulation, crimp, i.e. a square trellis, mesh, pattern, is formed on a glass substrate by a lithographic technique by direct nanoimprinting (direct NIL).

More exactly, one begins by making a silicon mold with a square trellis, mesh, pattern of circular pads. This mold is placed in a lithographic nanoimprinting machine and a glass substrate is also placed on the mold. It is then heated in vacuo to a temperature above the glass transition temperature of the substrate. And the pattern of the layer of photonic crystals on the mold is then embossed on the glass surface by the piston, plunger, of the lithographic nanoimprinting machine, and the glass substrate is released from the mold by cooling.

A transparent anode in Indium Zinc Oxide (IZO)is deposited by sputtering on the glass substrate and the other layers of the OLED are then formed by evaporation in vacuo.

Document U.S. Pat. No. 6,670,772 [5] relates to the preparation of an OLED display which comprises a substrate, a thin film transistors (TFTs) formed on the substrate, an insulating layer formed on the TFT layer and defining a periodic grating structure, a first electrode layer formed over the grating structure and conforming to the grating structure, an OLED material layer formed over the first electrode layer and conforming to the grating structure, and a second electrode layer formed over the OLED material layer and conforming to the grating structure.

Document US-A1-2005/0088084 [6] describes a device substantially analogous to the one of document [5].

Document US-A1-2001/0038102 [7] describes a light emitting device, such as an OLED, which comprises a substrate including two elements, i.e. a transparent base and a photopolymerizable resin.

The photopolymerizable resin is applied on the upper surface of the transparent base.

With an embossing mold provided with undulations, crimps, ribs, a structuration may be formed in the resin layer.

Next, a first electrode layer, an active layer, and a second electrode layer are successively deposited on the structured resin layer.

An overall structuration of the diode, as the one achieved in the documents cited earlier allows the folding of dispersion relations of the surface plasmon modes associated with all the metal-dielectric interfaces as this is mentioned in documents [4] and [5]. These modes which are evanescent by nature, become radiative, causing enhancement of the extraction of light which is indicated in documents [4] to [7].

If one is now interested in methods for making a nanostructured substrate, among the methods mentioned in the literature, nano-imprinting (nano-imprint) is noted, which is notably described in documents [4] and [7].

This technique for making a nanostructured substrate is compatible with the manufacturing methods used in micro-electronics.

This technique also allows bulk production when the processes are well controlled.

However, as this is specified in article [7] and patent [7], the shape of the pattern forming the structure is directly related to the mold used and several molds are therefore required for making different patterns and for making a complex nanostructured surface.

Further, both in the case of the nano-imprinting technique and in the case of the other techniques for preparing substrates with nanostructured surfaces, controlling the shape of the pattern is crucial, and may prove to be critical, since this shape has repercussions on all the layers deposited subsequently in a conforming way on this surface and therefore on the operation of the whole of the finally manufactured device on this substrate such as an OLED.

Indeed, if a pattern has too abrupt edges or slopes, as this is illustrated in FIG. 3A, short circuit (26) phenomena may occur between both electrodes (21,23), making the OLED unusable.

Further, (see FIG. 3B), like all methods for manufacturing substrates with nanostructured surfaces, nano-imprinting may also locally produce patterns with defects (27) such as spikes, asperities, bumps, or significant roughness. The presence of these local defects (27) promotes the occurrence of short circuits (26).

Moreover, as regards colored filtering, the solution presently used which is illustrated in FIG. 4, consists of positioning above the OLED element (41), colored filters (42) which are adhered via an adhesive layer (43) on the cathode of the OLED. The OLED is deposited on a control circuit (IC)(44) with which each pixel may be driven independently. The control circuit comprises insulating layers (45), a layer of transistors (46) a substrate (47), and metal connections (48) as well as an electronic system (49). This solution even further reduces the amount of emitted light.

Another solution consists of making metal-dielectric lattices with metal lines and dielectric lines, as this is illustrated in FIG. 5, in order to act on the effective optical index of the material so as to achieve colored filtering. By modifying the width of the metal line and of the dielectric line it is possible to select the color which will be extracted from the OLED.

More specifically, lithography and an etching step are carried out (FIG. 5A) in a metal layer (51), followed by deposition of dielectric (52) (FIG. 5B) and a Chemical Mechanical Polishing (CMP) step, and an anode (53) is thereby obtained with patterns (54), the characteristic dimensions of which are of the order of 100 nm. The dielectric layers and the organic emitting layers of the OLED (55) which emit white light and finally the semi-transparent cathode layer (56) are then deposited on the anode.

The main difficulty of this solution comes from the CMP step which is difficult to apply, especially in the case of different densities of patterns to be polished. Indeed, for different pattern densities, the polishing rates are different and fictitious patterns have therefore to be added in order to homogenize the polishing rates. This causes a loss of functional space for light emission. It is then difficult to produce pixels side by side with different colored filtering.

Therefore, considering the foregoing there exists a need for a method for manufacturing an electrode, such as anode, comprising a metal/dielectric nanostructuration on a substrate, for an organic light-emitting diode OLED, which allows such an nanostructured electrode, such as an anode, to be prepared in a simple, reliable, reproducible way and in a limited number of steps, regardless of the type, the shape and the complexity of this nanostructuration and of the patterns which may make it up.

Further, there exists a need for such a method with which it is possible to control, to perfectly, very accurately, monitor the nanostructuration, and notably the shape of the patterns which may make up the latter.

There further exists a need for such a method with which colored filtering may be obtained while avoiding the etching step in a metal, the step for depositing a dielectric/filling with a dielectric, and especially the chemical mechanical polishing step, with all the difficulties which it causes.

This method should finally be totally compatible with the manufacturing methods applied in micro-electronics and notably with the different methods used in the manufacturing of OLEDs.

In other words, there exists a need for a method for manufacturing an electrode such as an anode, comprising a metal/dielectric nanostructuration on a substrate, for an organic light-emitting diode OLED, which i.a. ensures enhancement of the extraction of light from the OLED, colored filtering without reduction in the emitted light, connection of the OLED preferably through the surface of the anode, individual electrical addressing of each pixel, and which gives the possibility of producing pixels side by side with different colored filtering.

The goal of the present invention is to provide a method for manufacturing an electrode, such as an anode, comprising a metal/dielectric nanostructuration, on a substrate, for an organic light-emitting diode OLED, which i.a. meets the needs and requirements listed above.

The goal of the present invention is also to provide a method for manufacturing an anode comprising a metal/dielectric nanostructuration on a substrate, for an organic light-emitting diode OLED, which does not have the drawbacks, defects, limitations and disadvantages of the methods of the prior art, and which solves the problems of the methods of the prior art.

### SUMMARY OF THE INVENTION

This goal and still other ones are achieved, according to the invention by a method for manufacturing an electrode for an organic light-emitting diode OLED, comprising a surface comprising a first dielectric nanostructuration and a second metal nanostructuration, on a substrate, in which the following successive steps are carried out:
a) a metal layer is deposited on a planar surface of a substrate;
b) on the metal layer, a dielectric layer, comprising said first dielectric nanostructuration which includes cavities which extend from the upper surface of the dielectric layer as far as the (to the) upper surface of the metal layer, is prepared;
c) the cavities of the first dielectric nanostructuration are at least partially filled with a metal, whereby the second metal nanostructuration is obtained.

According to a first embodiment, during step b), the dielectric layer comprising the first nanostructuration may be prepared by depositing a layer (of) in a dielectric material and then a resin layer on the metal layer, by proceeding with lithography of the resin layer in order to remove the resin in areas corresponding to the cavities to be defined in the dielectric layer, by etching the layer in a dielectric material in order to define the cavities, and by removing the resin.

Advantageously, lithography of the resin layer may be achieved by a method selected from optical lithography, electronic lithography, UV-assisted nano-imprinting lithography, and thermal nano-imprinting lithography.

Advantageously, in this first embodiment, the dielectric material may be selected from SiO₂, HfO₂ and all electrically insulating materials.

Advantageously, in this first embodiment, the resin may be selected from thermoplastic resins and thermosetting resins such as polystyrenes (PS), polymethyl methacrylates (PMMAs), unsaturated polyesters, epoxy resins, phenolic resins, polyimides, polyamides, polycarbonates, polyolefins, such as polypropylenes, POSS or polyhedral oligomeric silsesquioxane, and mixtures thereof.

According to a second embodiment, during step b) the dielectric layer comprising the first nanostructuration may be prepared by depositing a layer of a dielectric resin or a layer of a resin or of a material, said resin or said material being capable of being transformed into a dielectric material, on the metal layer, by proceeding with lithography of the layer in a resin or in a material, capable of being transformed into a dielectric material in order to define the cavities therein, and by transforming the resin or the material capable of being transformed to a dielectric material, into a dielectric material, by heat treatment.

In this second embodiment, it is the heat treatment which transforms the resin or the material into a dielectric material.

Advantageously, in this second embodiment, the dielectric layer may be in a dielectric material selected from materials called “spin on glass” materials or “centrifuged glasses” prepared from precursor materials (i.e. materials capable of being transformed into a dielectric material) such as Hydrogen SilsesQuioxane (HSQ); or PolyhedralOligomeric SilSesquioxanes (POSS).

In this second embodiment, it may be considered that a resin, for example, is deposited which after treatment, will be close to glass or SiO₂ because of its composition and its properties.

Advantageously, in this second embodiment, lithography of the layer in a resin or in a material capable of being transformed into a dielectric material may be carried out by a method selected from optical lithography, electronic lithography, UV-assisted nano-imprinting lithography, and thermal nano-imprinting lithography.

Advantageously, the substrate may be in a material selected from glass, transparent ceramics and transparent plastics.

Advantageously, the metal layer may be made in a metal selected from platinum, cobalt, nickel, iron, silver, aluminium, iridium, gold, molybdenum, palladium; and alloys thereof.

Advantageously, step c) may be performed by, carried out by, an electrochemical method selected from electro-deposition methods with imposed current or potential and (currentless) electro-reduction methods without any current called “electroless” methods.

Advantageously, the cavities of the first nanostructuration of the dielectric layer may be filled with a metal at least as far as (at least up to) the upper surface of the dielectric layer.

Advantageously, the cavities of the first nanostructuration of the dielectric layer may be filled with a metal beyond the upper surface of the dielectric layer i.e. the metal juts out from this surface.

Advantageously, the metal which juts out beyond the upper surface of the dielectric layer may form relief patterns with a height from 1 to 100 nm relatively to the level of the upper surface of the dielectric layer.

Advantageously, the first nanostructuration or dielectric nanostructuration is composed of a periodic lattice, such as a one-dimensional lattice or a two-dimensional lattice.

More particularly, the first nanostructuration may be a lattice of lines with periodic patterns of period P1 preferably from 100 nm to 1 μm, more preferably from 200 to 600 nm and with a height hl preferably from 5 nm to 100 nm, or a lattice of pads.

Advantageously, the lines of the first nanostructuration may have a width from 50 nm to 550 nm.

When the first nanostructuration is a lattice of lines, then the second nanostructuration is also a lattice of lines with periodic patterns of period P2 preferably from 100 nm to 1 μm, more preferably from 200 nm to 600 nm, and with a height h2 preferably from 5 nm to 100 nm.

It should be noted that both nanostructurations necessarily have the same period.

Advantageously, the lines of the second nanostructuration have a width from 50 nm to 550 nm.

For enhancing the extraction in the visible domains, it is preferable to use lattices having a period comprised between 200 nm and 600 nm.

For colored filtering, it is preferable to use (metal/dielectric) lattices having a period comprised between 300 nm and 600 nm.

The aim may be to either enhance the extraction or the colored filtering, but generally, both of these goals are sought.

In the alternative, the first nanostructuration may be a lattice of pads.

The method according to the invention may be defined as a method for making metal and dielectric nanostructures for colored filtering and enhancement of the light extraction in organic light-emitting diodes OLEDs. The method according to the invention may more particularly be defined as a method for making metal/dielectric lattices allowing extraction enhancement, colored filtering and electrical connection of an OLED notably through the surface of the anode.

The method according to the invention comprises a specific succession of steps which has never been described nor suggested in the prior art, such as notably illustrated by the documents cited above.

With the method according to the invention colored filtering may be obtained without any metal etching step, nor any dielectric filling step, nor any chemical mechanical polishing (CMP) step which, in the methods of the prior art, are the steps which are the most difficult to apply.

In particular, the method according to the invention does not include any chemical mechanical polishing step and the method according to the invention consequently avoids all the drawbacks related to this operation. Notably, with the method according to the invention nanostructurations may easily be made with different pattern densities without it being necessary to use fictitious patterns, required during this chemical mechanical polishing. By suppressing, by means of the method according to the invention, these fictitious patterns, the emission surface is thereby increased.

Accordingly, with the method according to the invention, pixels may easily be made side by side with different colored filterings.

The method according to the invention globally enhances the extraction of light from the OLED and makes it possible to electrically address each pixel individually.

The method according to the invention for manufacturing an electrode, such as an anode, comprising a surface with a metal/dielectric nanostructuration on a substrate for an organic light-emitting diode OLED, i.a. meets the whole of the needs listed above and provides a solution to the problems of the methods of the prior art.

The method according to the invention is simple, reliable, easy to apply and with it, it is possible to easily prepare in a controlled, reproducible way, surfaces for which nanostructuration is perfectly, accurately monitored, controlled.

The shape of the patterns composing the extraction lattices of the diode is generally perfectly controlled, and enhanced but also specifically modulated extraction may be obtained.

The invention further relates to a method for manufacturing an organic light-emitting diode OLED comprising at least one step for manufacturing an electrode comprising a surface comprising a first dielectric nanostructuration and a second metal nanostructuration on a substrate, said step being carried out by the method as described above.

This method for manufacturing an OLED inherently has all the advantages and effects already mentioned above related to the method according to the invention for manufacturing an electrode comprising a surface comprising a metal nanostructuration and dielectric nanostructuration, on a substrate, and the advantages of the method for manufacturing an organic light-emitting diode OLED according to the invention are essentially due to the method according to the invention for manufacturing an electrode comprising a surface comprising a metal nanostructuration and a dielectric nanostructuration and they have been already widely discussed above.

Advantageously, in the method for manufacturing an OLED according to the invention, a first electrode is manufactured comprising a surface comprising a first dielectric nanostructuration and a second metal nanostructuration, on a substrate, by the method according to the invention, and then one or more organic emitting layers conforming to the nanostructured surface of the first electrode, and a second electrode layer conforming to the nanostructured surface of the first electrode are successively deposited on the nanostructured surface of the first electrode.

Preferably, the first electrode is an anode and the second electrode is a cathode.

Advantageously, one or more other layer(s) conforming to the nanostructured surface of the first electrode, selected from a holes injection layer, a holes transport layer, an electrons injection layer, an electrons transport layer, a holes blocking layer, an electrons blocking layer and a thin film transistors (TFT) layer may further be deposited on the first electrode, two or more among this(these) other layer(s), the organic emitting layer(s), the first electrode layer and the second electrode layer being optionally merged.

The invention will be better understood upon reading the detailed description which follows, made as an illustration and not as a limitation, with reference to the appended drawings wherein:

### SHORT DESCRIPTION OF THE DRAWINGS

FIG. 1 is a schematic vertical sectional view of an Organic Light-Emitting Diode (OLED);

FIG. 2 is a schematic vertical sectional view of an OLED with nanostructurations allowing optical extraction;

FIG. 3A is a schematic vertical sectional view of an OLED for which the organic layers, the anode and the cathode have patterns with a too large slope capable of causing short-circuits;

FIG. 3B is a schematic vertical sectional view of an OLED for which the organic layers, the anode and the cathode have patterns with defects capable of causing short-circuits;

FIG. 4 is a schematic vertical sectional view of an OLED according to the prior art in which colored filtering is obtained by adhesively bonding colored filters on the OLED element;

FIGS. 5A-5C are schematic vertical sectional views which illustrate the successive steps for manufacturing an OLED without any colored filter in which colored filtering is obtained by metal-dielectric lattices;

FIGS. 6A-6G are schematic vertical sectional views which illustrate the successive steps for manufacturing an electrode (anode) comprising a surface comprising a metal nanostructuration and a dielectric nanostructuration on a substrate by the method according to the invention (FIGS. 6A-6E), and then the steps for manufacturing an OLED on this electrode (FIGS. 6F-6G).

### DETAILED DISCUSSION OF PARTICULAR EMBODIMENTS

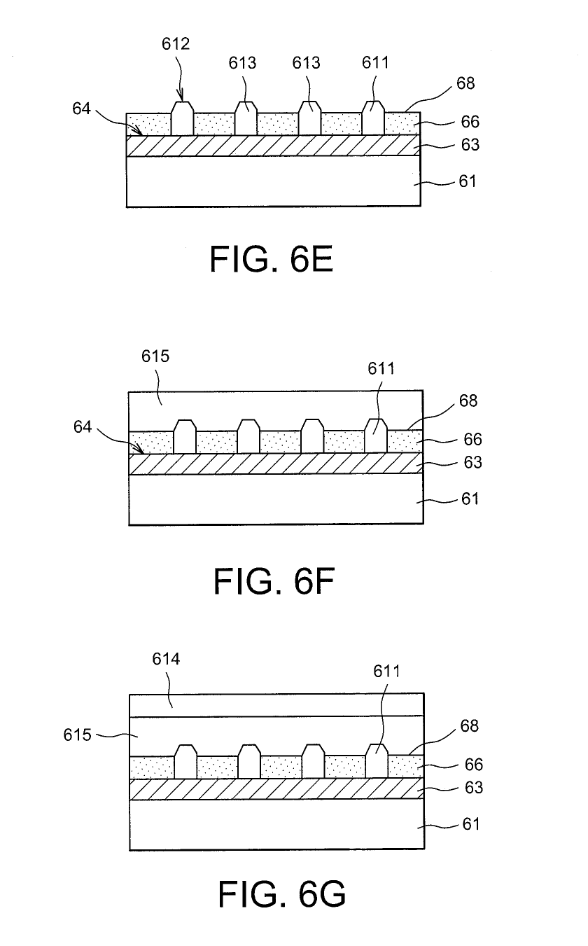

The method for manufacturing, according to the invention, an electrode such as an anode for an organic light-emitting diode OLED, comprising a surface comprising a metal nanostructuration and a dielectric nanostructuration, on a substrate, (See FIGS. 6A, 6B, 6C, 6D, 6E, 6F, 6G), first of all comprises a step during which a metal layer (63) is deposited on a planar surface (62) of a substrate (61).

The substrate or superstrate (61) according to the arrangement of the organic light-emitting diode may be in any material suitable for manufacturing a substrate for an OLED.

The substrate (61) may be a transparent substrate, i.e. which transmits light, preferably visible light, or else an opaque substrate.

Of course, it is desirable that the substrate transmits light, i.e. is transparent, in the case when light emission is accomplished through the substrate which is then rather generally a “superstrate”.

Examples of adequate transparent materials are glasses, transparent ceramics and transparent plastics.

In the case when light emission is accomplished through the upper electrode which is generally the cathode, then the substrate may be a substrate transmitting light or a substrate reflecting light or a substrate absorbing light.

The substrate (61) includes at least one planar surface, generally its upper surface (62) on which the metal layer (63) is deposited.

The substrate (61) may thus have the shape of a plate or platelet, wafer, comprising two parallel planar surfaces, for example square, rectangular or further circular surfaces.

This platelet may have a thickness from one or a few microns (2, 3, 5, 10 μm) to one or a few millimeters (2, 3, 5, 10 mm) preferably from 1 μm to 3 mm, preferably between 10 μm and 2 mm, and a surface for example with the shape of a disc having a diameter of 20 or 30 cm.

The metal layer (63) is generally in a metal selected from platinum, cobalt, nickel, iron, silver, aluminium, iridium, gold, molybdenum, palladium; and their alloys.

The metal layer (63) may be deposited by a method selected from chemical vapor deposition (CVD), plasma-enhanced (assisted) chemical vapor deposition (PECVD or PACVD), physical vapor deposition (PVD) and sputtering.

The metal layer generally has a thickness from 10 nm right up to 100 or a few hundred nanometers, for example 200, 300, 500, 600 or 1,000 nm; preferably the metal layer has a thickness from 10 nm to 200 nm, more preferably from 100 nm to 300 nm.

In a second step of the method according to the invention, on the metal layer (63) or more specifically on the upper surface (64) of the metal layer (63), a dielectric layer (65) is prepared, comprising a first nanostructuration (66), which may also be designated as dielectric nanostructuration (66). This nanostructuration (66) includes cavities (67) which extend from the upper surface (68) of the dielectric layer (65) as far as (to) the upper surface (64) of the metal layer (63).

In a first embodiment of the second step of the method according to the invention, the dielectric layer (63) comprising the first nanostructuration (66) is prepared by depositing a layer in a dielectric material (65) and then a resin layer (69) which may be called a resin layer to be structured on the metal layer (63) (see FIG. 6A); by proceeding with lithography (see FIG. 6B) of the resin layer (69) in order to remove the resin in areas (610) corresponding to the cavities (67) to be defined in the dielectric layer (65), by etching the dielectric layer (65) for defining the cavities (67) (see FIG. 6C), and finally by removing the resin (see FIG. 6D).

The deposited dielectric material may be selected from SiO₂, HfO₂ and electric insulators, in other words electrically insulating materials.

This layer in a dielectric material may be deposited by a method selected from chemical vapor deposition (CVD), plasma-enhanced (assisted) chemical vapor deposition (PECVD or PACVD), physical vapor deposition (PVD) and sputtering.

Advantageously, this layer in dielectric material generally has a thickness from 10 nm to 200 nm.

On the thereby deposited dielectric material layer, a resin layer (69) is deposited (see FIG. 6A).

In this first embodiment of the second step of the method according to the invention, the resin (69) is thereafter eliminated, removed before proceeding with the filling of the cavities (67) of the dielectric nanostructurations and is therefore not present during this step, nor next during the subsequent steps for manufacturing the OLED, nor in the final ready-to-operate OLED.

Accordingly, it is not required that the applied resin be compatible with the method used for filling the cavities of the first nanostructurations, such as an electrochemistry method. It is neither not required that this resin be able to withstand the subsequent steps for manufacturing the OLED, such as depositions of layers, annealing, etching operations etc.

Finally, it is not required that this resin have properties required for being able to withstand the conditions of use of the OLED such as heat resistance, resistance to ageing and mechanical strength.

In this first embodiment of the second step of the method according to the invention, the selection of the resin may therefore generally be simply made depending on its resolving capacities and depending on the lithographic technique used in the following step. Thus, in the case when an optical or electronic lithographic technique or UV-assisted nano-imprint lithographic technique is used, a photosensitive resin will generally be used such as a resin based on methacrylate groups or a polyhydroxystyrene resin.

A wide selection of commercial products is available according to the method used.

In the case when a thermal nano-imprint lithographic technique is used, the resin is not mandatorily photosensitive, and it should then simply have a melting or glass transition temperature.

Let us recall that the glass transition temperature (Tg) is the temperature at which certain polymers pass from a glassy hard solid state to a plastic state. Above this temperature, it may be stated that these resins, polymers are fluid and may therefore flow.

The resin, in the case when a thermal nano-imprint lithographic technique is used may therefore be advantageously selected from thermoplastic resins and thermosetting resins.

By resin is also meant mixtures of two or more resins.

Exemplary resins are polystyrenes (PS), polymethyl methacrylates (PMMAs), unsaturated polyesters, epoxy resins, phenolic resins, polyimides, polyamides, polycarbonates, polyolefins such as polypropylenes, POSS or polyhedral oligomeric silsesquioxane, and mixtures thereof.

The resin of the resin layer (69) may optionally be subject to a heat treatment notably in the case of POSS, if it desired to achieve transformation into a dielectric material. Otherwise for the nano-imprint use, such a heat treatment is not absolutely necessary.

In the case of thermosetting resins, polymers, the latter may be applied as a composition in two portions comprising the precursors of the resin with for example a formulation on the one hand and a cross-linking, setting agent, on the other hand.

The organic resin layer (69) may be deposited by a technique selected from the following techniques:
dip coating;
spin-coating;
laminar-flow-coating;
spray-coating;
soak coating;
roll-to-roll process;
painting coating;
screen printing.

All these techniques may be used in the method of the invention especially if it is desired to deposit<<thick>>layers, such as for example of the order of 10 μm.

In these techniques, notably in the spin coating technique, a solution of the resin, of the organic polymer is used in a solvent, generally an adequate organic solvent. As an example, if the polymer is polymethyl methacrylate (PMMA), it is possible to use a solution of this polymer in toluene

The preferred technique is the spin coating technique or else the spray-coating technique. In addition to these techniques in solution, it is also possible to use for depositing the resin layer, chemical vapor deposition (CVD) or plasma-enhanced (assisted) chemical vapor deposition (PECVD or PECVD).

The deposited layer is preferably a thin resin layer or a resin film (69). By thin layer (69), is generally meant that the resin layer (69) has a thickness comprised between a few nanometers and a few hundred nanometers, preferably from 10 to 500 nm.

At the end of the deposition of the resin, it is proceeded with lithography of the resin layer (FIG. 6B) in order to remove the resin in areas (610) of the resin layer (69) corresponding to the cavities (67) to be defined in the dielectric layer (65).

In other words, during this lithographic step for the deposited resin layer (69), an etching mask is prepared, and a pattern is thereby defined in the resin layer, which corresponds to the pattern which one desires to then obtain in the underlying dielectric material layer (65).

As this has already been specified above, the lithographic technique may be an optical or electronic technique, a UV-assisted nano-imprint lithographic technique or a thermal nano-imprint lithographic technique.

According to the first embodiment of the second step of the method according to the invention, by means of the resin layer prepared by lithography (lithographed) as described above and playing the role of a mask, etching of the dielectric layer (65) (see FIG. 6C) is then carried out. Etching of the dielectric layer 65) may be achieved by any known standard etching method for example selected from reactive wet or dry etching methods such as reactive ion etching or RIE. With these methods it is possible to transfer the pattern of the resin layer (69) to the underlying dielectric material layer (65).

A first nanostructuration (66) or dielectric nanostructuration is thereby defined in the dielectric layer (65), including cavities (67) which extend from the upper surface (68) of the dielectric layer as far as (to) the upper surface (64) of the metal layer (63).

The nanostructuration of the dielectric layer may be formed by (may consist in) a periodic lattice.

This periodic lattice may be a one-dimensional lattice or a two-dimensional lattice.

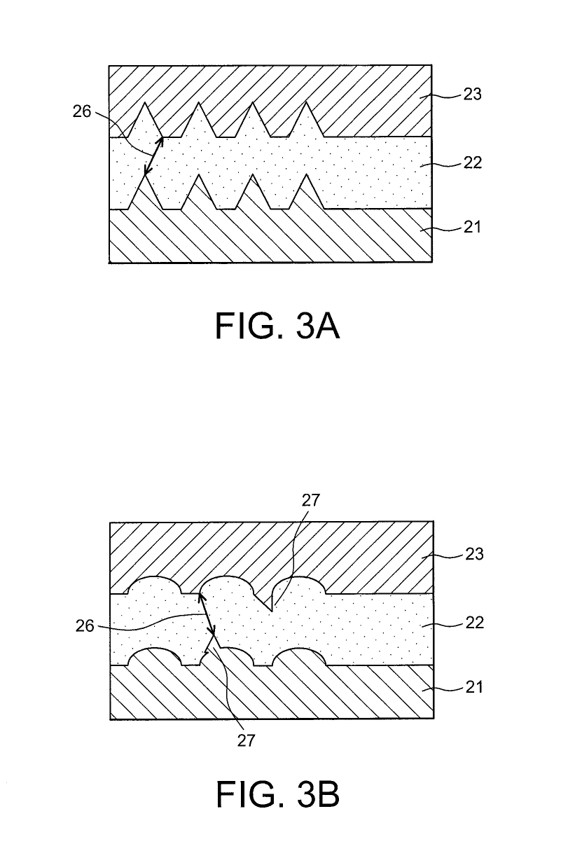

Such a one-dimensional lattice may for example be a lattice of lines with periodic patterns of period P (P1 referring to the first nanostructuration) and of height h (h1 referring to the first nanostructuration) (see FIG. 2).

The period P1 may be from 100 nm to a few micrometers, preferably from 100 nm to 1 μm, preferably from 200 to 600 nm, and the height h1 may be from at least 5 nm to 100 nm, preferably from 5 nm to 40 nm.

The lattice may be a two-dimensional lattice. Indeed, it is possible to make lattices with holes of different shapes. In order to determine the best geometry, simulations of the optical behavior of these structures have then to be carried out. Such a two dimensional lattice may notably be selected from square lattices, triangular, rectangular, hexagonal lattices and more complex lattices such as Archimedean lattices.

The lattice may also be a lattice of pads.

It should be noted that the first nanostructuration generally has simple unrounded geometrical patterns.

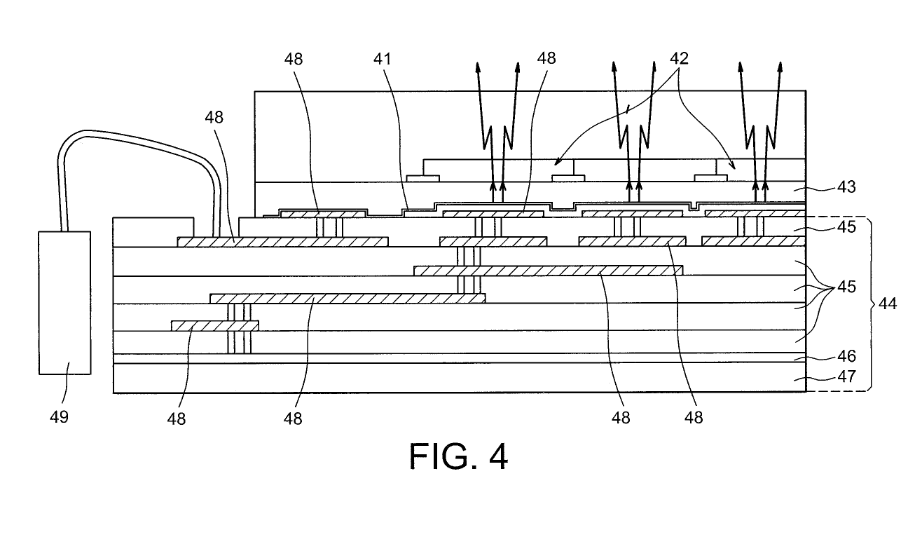

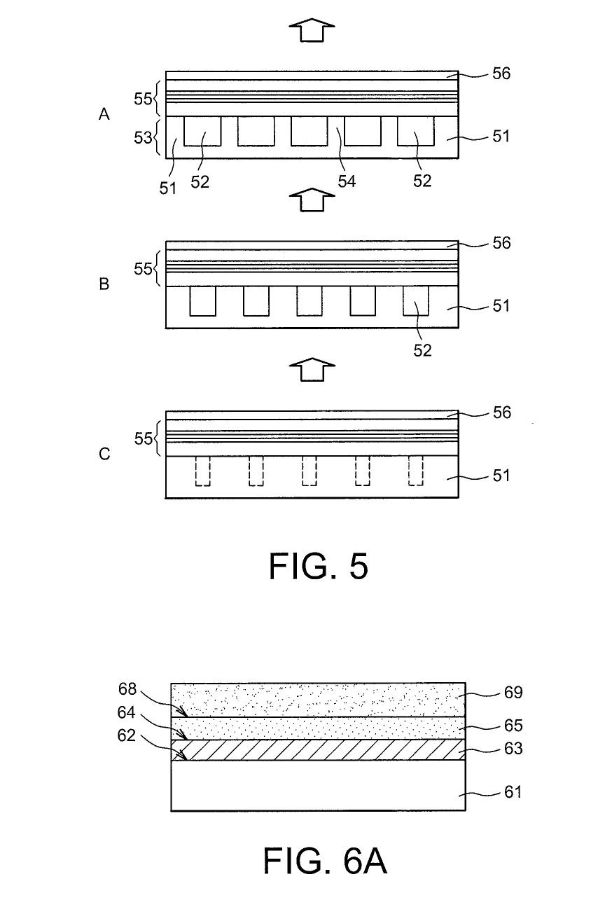

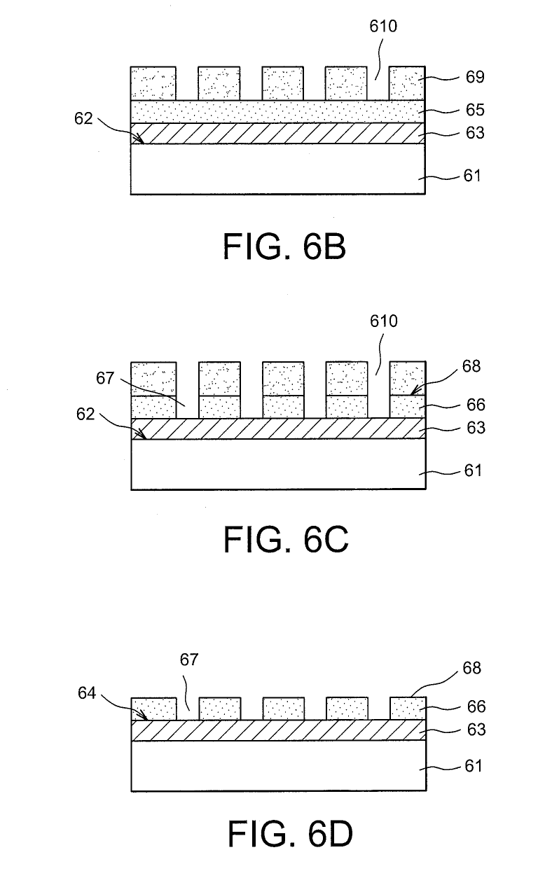

For example, the lines may have a triangular (FIG. 3A), rectangular or square cross-section (FIGS. 4C, 4D). Lines with a rectangular or square cross-section will be preferred, with a height h1 as defined earlier and a width of the lines from 50 nm to 550 nm.

The nanostructuration (66) obtained in the dielectric layer (65) includes cavities defined between the patterns in dielectric material. This nanostructuration may be described as a first nanostructuration or dielectric nanostructuration.

In the case of a line lattice, these cavities are formed by the voids, valleys existing between the lines. When the lines have a rectangular or square cross-section, the cavities also generally appear as lines with also a rectangular or square cross-section with a height (depth) h1 as defined earlier, and a width from 50 nm to 550 nm.

It is then proceeded with removing the resin (see FIG. 6D) by any method known to one skilled in the art such as a method known as “stripping” comprising plasma treatment and/or wet etching steps.

In a second embodiment of the second step of the method according to the invention (not shown in the figures), the dielectric layer comprising nanostructurations may be prepared by depositing a layer in (of) a dielectric resin or in a resin or in a material, said resin or said material being capable of being converted into a dielectric material or resin, on the metal layer and by means of lithography (by lithographing), by printing or etching the layer in a dielectric resin or in a resin or a material capable of being transformed into a dielectric material or resin so as to define the cavities therein.

This dielectric material such as a resin is generally different from the resin of the first embodiment essentially because of its chemical formulation which changes and because materials such as resins applied in the second embodiment are generally stable for higher temperatures for example at 400° C./500° C., which is not obvious to obtain with the other resins.

Typically, these materials such as resins are not purely organic and contain mineral components such as silicon.

The dielectric material such as a dielectric resin is present when it is proceeded with filling the cavities of the dielectric nanostructurations as well as during subsequent steps for manufacturing the OLED. This resin is also present in the final ready-to-operate OLED.

Accordingly, unlike the resin used in the first embodiment, it is required that the dielectric material such as a resin applied in this second embodiment of the second step of the method according to the invention, be compatible with the method used subsequently for filling the cavities of the first nanostructurations, such as an electrochemistry method.

More specifically, the dielectric material such as a dielectric resin used in this second embodiment of the second step of the method according to the invention should generally be selected so as to be able to withstand the solutions used for achieving electrochemical growth of the metal nanostructurations during step c) of the method according to the invention, so that the first nanostructuration, the dielectric patterns are not altered, deteriorated.

It is also required that this resin be able to withstand the subsequent steps for manufacturing the OLED, such as depositions of layers, annealings, etchings etc.

Finally, it is required that this material, for example this resin, have the required properties in order to be able to withstand the conditions of use of the OLED, such as heat resistance, resistance to ageing and mechanical strength.

The dielectric material, for example the dielectric resin, is therefore selected depending on the criteria listed above, but also like the resin applied in the first embodiment, according to its resolving capacities and according to the lithographic method applied.

The material or resin which will be transformed into a dielectric material is generally selected from materials called spin-on-glass or centrifugal glasses.

These glasses are prepared by spreading by centrifugal coating (whirler, spin coating) of a solution.

After a heat treatment generally consisting in drying, evaporating and then annealing of the material or of the resin capable of being transformed into a dielectric material or resin, a layer of dielectric material or resin is obtained, for example a layer essentially consisting of SiO₂.

The precursors or materials capable of being transformed into a dielectric material may be selected from hydrogen silsesquioxane (HSQ); and POSSes.

If a lithographic method by thermal nano-imprinting is used for etching this layer, the dielectric resin or material is advantageously selected from the organic resins already mentioned above, provided that they have a glass transition temperature Tg or a melting temperature above the subsequent deposition temperature(s) of one or more other layer(s).

Typically, this Tg or this melting temperature is above the temperature for depositing the OLEDs and the metal film for the anode.

By glass transition temperature or melting temperature above the deposition temperature(s), is generally meant that the glass transition temperature or the melting temperature of the organic resin is greater by at least 5° C., and preferably by at least 20° C. than the highest deposition temperature used for the subsequent deposition of the other layer(s).

This(these) other layer(s) is(are) organic or mineral or metal layers as well which are part of the structure of an organic light-emitting diode and will be described in detail below.

By selecting such an organic resin with such a glass transition temperature or such a melting temperature, in order to form the organic resin layer, which then forms the nanostructuration of the electrode, it is avoided that the nanostructuration be thermally deformed during the steps for depositing layers which then occur in the manufacturing of the OLED, and thus it is made sure that the dielectric nanostructuration obtained at the end of the method according to the invention is entirely preserved after each step for manufacturing the OLED and at the end of the full method for manufacturing the OLED.

This layer in dielectric resin or in a material capable of being transformed into a resin or into a dielectric material is deposited by a method selected from the methods already mentioned earlier for the organic resin layer within the scope of the first embodiment.

The thickness of the layer of dielectric resin or of resin or material capable of being transformed into a resin or into a dielectric material is generally from 10 nm to 100 nm.

At the end of the deposition of the dielectric resin layer or of the layer in a material or resin capable of being transformed into a dielectric material or resin, it is then proceeded in accordance with the second embodiment of the second step of the method according to the invention, with lithography, etching, printing of this layer so as to define therein the intended cavities and to thereby prepare a dielectric layer comprising the sought nanostructurations.

The lithography of this layer is achieved by one of the techniques already mentioned earlier for the lithography of the organic resin layer in the first embodiment of the second step of the method according to the invention.

If a layer of material or resin capable of being transformed into a dielectric resin or material is used, the material or the resin is transformed into a dielectric resin by heat treatment as this was described earlier in the case of “centrifuged glasses”.

The nanostructuration of the layer of dielectric material obtained at the end of the second step of the method according to the invention, in this second embodiment, is generally analogous to the one obtained in the first embodiment.

Following the second step of the method according to the invention, the third step (step c)) of the method according to the invention is carried out, during which the cavities (67) of the nanostructuration (66) of the dielectric layer (65) are at least partly filled with a metal or alloy (611), preferably the cavities (67) are at least partly filled up to the upper surface (68) of the dielectric layer (65).

This metal or alloy (611) may be the same metal or alloy as the one which forms the metal layer, or else this may be a different metal or alloy. This metal or alloy (611) is generally selected from platinum, cobalt, nickel, iron, silver, aluminium, iridium, gold, molybdenum, palladium; and their alloys.

The cavities (67) are at least partly filled with the metal or alloy.

If the filling is partial filling, then the metal pattern is a<<recessed>>pattern.

Preferably, the cavities (67) are filled with the metal or alloy at least up to the upper generally planar surface (68) of the dielectric layer (65). However, it will not however be sought to systematically obtain a perfectly planar surface of the metal (612). That is to say that it will generally not be sought to obtain a perfectly planar upper surface (612) of the metal or alloy (611) filling the cavities (67), exactly located in the same plane as the upper surface (68) of the dielectric layer (the upper surface (68) of the dielectric layer is generally composed of the upper surface, generally a planar surface of the patterns (66) such as dielectric lines defined in the dielectric layer), not having any relief relatively to this upper surface of the dielectric layer.

Indeed, it is generally advantageous that the metal or alloy (611) fills the cavities (67) beyond the generally planar upper surface (68) of the dielectric layer and therefore juts out from this upper surface in order to form raised patterns (613) protruding relatively to the plane of the upper surface (68) of the dielectric layer (65).

In other words, the presence of a topography, preferably a small topography is generally advantageous since it may give the possibility of enhancing the extraction without however generating defects in the OLED.

By “small topography”, is meant that the height of the metal patterns (613) which are protruding, in relief, relatively to the level of the upper surface of the dielectric layer may range from one to a few nanometers (2, 3,4, 5 nm) up to 10 to a few tens of nanometers, for example 100 nm.

The shape of these metal patterns, of this metal topography may be arbitrary.

This shape is generally not perfectly controlled.

The filling (FIG. 6E) of the cavities of the nanostructuration of the dielectric layer with a metal is carried out by an electrochemical method.

More specifically, the filling of the cavities consists of carrying out electrochemical growth of metal islets in the cavities of the dielectric layer.

This electrochemical growth may be achieved with two types of methods:
electro-deposition methods also called electrolytic-deposition or electroplating methods: they are conducted by imposing a potential or a current;
electro-reduction methods without any current called “e-less” methods.

Growth of the deposit by electro-deposition takes place on the metal or semiconducting surfaces which are biased; the reduction of the metal cations contained in the electrolyte (deposition bath) occurs on the biased surfaces. Controlling the growth is accomplished by adjusting the potential or the imposed current. Although the potentiostatic mode (controlled potential) gives the possibility of better controlling the interface reactions, industrial processes are often galvanostatic (controlled current). According to the imposed pulsed or constant potential or current, the nature and the structure of the deposit varies. The growth mode also depends on the interaction forces between the substrate and the deposited metal as this is mentioned in the document of E. Budevski, G. Staikov, and W. J. Lorenz, Electrochemical Phase Formation and Growth, VCH, Weinheim 1996 [8].

In the second case, reduction of the metal cations is accomplished on the substrate by a reducing agent also contained in the deposition solution. The reduction reaction is catalyzed by the substrate itself or by nuclei (seeds) deposited beforehand in order to activate the surface (a step required in the case of non-conducting substrates). The drawback of the e-less method is the difficulty in controlling the beginning and the end of the reaction but the temperature, the deposition time and the concentrations of the different reagents of the electrolyte may be varied. Unlike the e-less method, electro-deposition provides the possibility of better controlling the method by adjusting the potential or the current in addition to the other parameters mentioned earlier (M. Paunovic, M. Electrochemical Deposition, (2006) [9]).

With electrochemical growth techniques, it is possible to obtain structures ranging up to nanometric sizes under optimized conditions. However, the size distribution, the density as well as the localisation of the nanostructures remain uncertain, random. Also, the coupling of these techniques with the use of a mask is a solution for obtaining regular structures with the desired dimensions, insofar that the deposition solutions are compatible with the material making up the mask.

In order to use, carry out the electro-deposition method, it is necessary to have an electric contact on the metal layer found under the dielectric layer and the mask. To do this, making a cut-out of the plate may be contemplated in order to remove the dielectric portion+mask part and to assume, take, the contact. In the case of “e-less” deposition, no plate preparation is required; on the other hand, it should be made sure that the deposition parameters such as the temperature and the pH are selected so that the mask or more exactly the nanostructuration in the dielectric (66) is not damaged.

A large number of standard methods exist such as the deposition of platinum [10], [11], [12], cobalt [13], [14], [15], nickel [16], [17], [18], [13], [19], iron [17], [14], [13], [19], silver [20], [21], [22], [23] etc. and they are performed in aqueous media.

Other depositions which are difficult to perform in an aqueous solution such as that of aluminium may be applied, carried out, in non-aqueous electrolytes such as ionic liquids [24], [25].

At the end of this step for filling the cavities of the nanostructuration of the dielectric layer, an electrode is thereby obtained such as an anode, comprising a surface both comprising a metal nanostructuration and a dielectric nanostructuration. The metal nanostructuration in fact corresponds to the cavities (67) of the first nanostructuration, which have been filled with metal (611).

Thus, in the case of a first nanostructuration or dielectric nanostructuration consisting in a lattice of lines, the second nanostructuration or metal nanostructuration also consists in a lattice of lines with periodic patterns of period P2 and with a height h2. The period P2 of the lattice of metal lines may be from 100 nm to a few micrometers, preferably from 100 nm to 1 μm, preferably from 200 nm to 600 nm, and the height h2 may be at least from 5 nm to 100 nm, preferably from 5 nm to 40 nm. The height h2 is generally equal to the height h1, but at this height h1, there is generally a reason to add the height of the possible metal topology above the upper surface of the dielectric layer so that the height of the patterns of the second nanostructuration will then be larger than the height h1.

When the lines of the dielectric nanostructuration have a rectangular or square cross-section, the lines of the metal nanostructuration also have a rectangular or square cross-section with a height h2 as defined above equal to that of the lines of the dielectric nanostructuration (plus possibly the height of the topology above the upper surface of the dielectric layer), and a width from 50 nm to 550 nm (see FIG. 6E).

Typically, the surface of the electrode may thereby include a lattice of dielectric lines with a width from 50 nm to 550 nm and a lattice of metal lines with a width from 50 nm to 550 nm.

By adjusting the width of the metal line and of the dielectric line, it is possible to easily select the color which will be extracted from the OLED.

This may be achieved by optical engineering calculations.

The optical indexes of the metal and of the dielectrics used have to be known and the geometry may thus be simulated in order to determine the best forms, shapes, to be achieved.

It is then possible to manufacture an organic light-emitting diode OLED which comprises as an electrode, preferably as an anode, the anode manufactured by the method according to the invention described above.

Any organic light-emitting diode may be manufactured by the method according to the invention, provided that at least one of its electrodes is prepared by the method according to the invention as described above.

In order to manufacture this organic light-emitting diode, the various layers making up an OLED are successively deposited on the surface with electrical and metal nanostructurations of the electrode, on a substrate, said electrode being prepared according to the method of the invention.

It should be noted that any description relating to the nature, to the number, to the arrangement, to the shape of the layers of the OLED, given in the following, is only given as an indication, as an illustration and not as a limitation and that the same advantages are obtained regardless of the number, the nature, and the arrangement of these layers of the OLED provided that at least one of the electrodes of the OLED is an electrode with a nanostructured surface prepared by the method according to the invention.

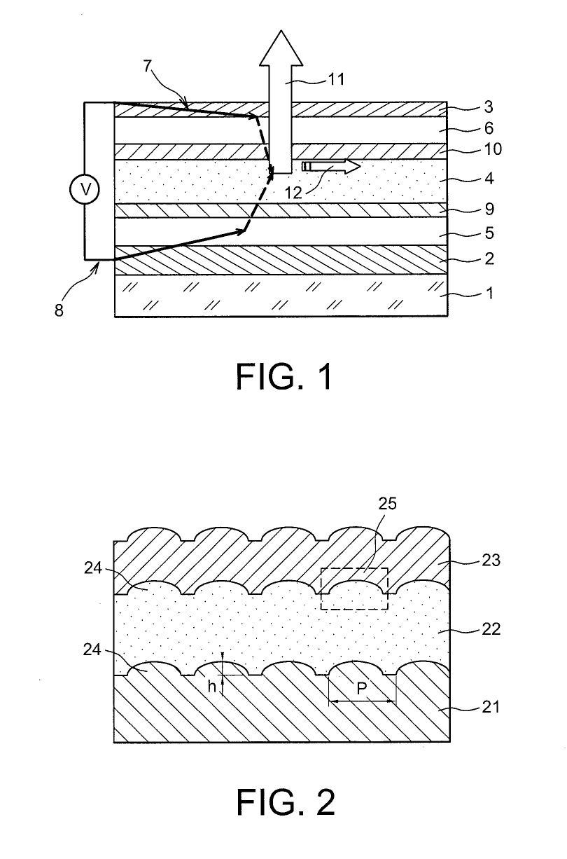

The OLED manufactured by the method for manufacturing an OLED according to the invention may be one of the OLEDs described above such as the one described in FIG. 1 or an OLED as described in document [5] or [6] or else further in document [7].

In the following, it will be assumed, but without this being able to be considered as any limitation, that the electrode manufactured by the method according to the invention is the anode.

Very generally, it is possible to deposit on the anode, itself deposited on the substrate, a cathode (614) and emissive organic layers (615), the light-emitting organic layers being deposited between the anode and the cathode. All of these depositions are of course, according to the invention, carried out in a conforming way with the nanostructured surface of the anode.

Above the anode, a holes (further called positive charges) transport layer which contains at least one compound for transporting holes, such as an aromatic tertiary amine compound, a polycyclic aromatic compound or a polymer for transporting holes, is generally deposited.

Between the holes transport layer and the anode, it may be necessary to provide a layer for injecting holes which for example comprises porphyrinic compounds or aromatic amines.

The holes injection layer and the holes transport layer are, according to the invention, conforming to the nanostructurations of the surface of the anode.

The holes injection layer and the holes transport layer may possibly coincide, merge.

Above the holes transport layer, one or more organic emitting layer(s) are deposited.

The OLED may only comprise a single emitting layer but it may possibly comprise several emitting layers, for example two or three superposed emitting layers.

In the case when three emitting layers are present, these layers may be layers which respectively emit in blue, green and red in order to provide white light (as defined in the 1931 or 1976 standard CIE diagram).

The effect of the metal/dielectric lattice on the emitted light may be determined by simulations.

The materials making up these emitting layers are known to one skilled in the art.

These emitting layers are conforming to the nanostructuration of the anode.

This(these) emitting layer(s) are generally deposited by thermal evaporation.

On the emitting layer(s), an electrons transport layer is deposited and then an electrons injection layer which are of course conforming to the nanostructuration of the anode. Both of these layers may coincide, merge, and they may possibly coincide, merge, with the emitting layer(s).

Finally (see FIG. 6G), the cathode (615) of the OLED is deposited which is also according to the invention conforming to the nanostructured surface of the anode.

In the present case, light emission occurs through the cathode, thus the latter should be transparent to the emitted light and may for example be in indium tin oxide (ITO), or in indium zinc oxide (IZO).

The cathode is generally deposited by evaporation, sputtering, or chemical vapor deposition.

Other layers, also conforming to the nanostructured surface of the anode may be provided, such as a holes blocking layer and an electrons blocking layer.

The invention will now be described with reference to the following examples, given as an illustration and not as a limitation.

### EXAMPLES

### Example 1

In this example, a substrate is prepared by the method according to the invention using a thermosetting resin, and then an organic light-emitting diode is prepared on said substrate by the method according to the invention.

The method for preparing the substrate comprises the following successive steps:
Deposition by PVD of the metal layer, for example in platinum or of a conducting layer with a thickness of 10 nm on the substrate;
Deposition (or coating) of the commercially available thermosetting resin Neb® 22 of Sumito Chemical Japan on an 8 inch silicon wafer;
Compression of the resin at 110° C. for 5 minutes under 300 mbars, by means of which a first nanostructuration is obtained which is a lattice of lines or a lattice of pads with a period from 200 nm to 600 nm and heights from 5 nm to 40 nm;
After printing, plasma etching of the so-called residual resin layer which is present under the printed patterns in order to expose the substrate and the metal layer;
Growing Cu or Au conducting structures by electrochemistry in the patterns generally created by printing and etching, until reaching the top of the thereby made holes.

It is possible to allow the growth to slightly jut out in order to generate a topography relatively to the resin layer.

These conducting patterns will therefore be in electrical contact with the underlying conductive layer.

These conductive patterns are surrounded by the dielectric resin and it is the whole of the conductive layer and of the structures produced by electrochemistry which forms the structured anode for the OLED.
Subsequent deposition of the OLED layers on the obtained nanostructured substrate.

### Example 2

In this example, a conductive or metal layer for example in TIN is deposited on a substrate. Next, a dielectric material layer is deposited (for example a 100 nm layer of silicon dioxide).

On this dielectric layer, optical lithography is carried out (at a wave length of 193 nm) with a commercial resin such as a resin available at Rohm and Haas, Clariant or Tok, for making lattices of lines or holes, the periods of which range from 200 nm to 600 nm.

After developing the resin, the dielectric layer is etched right up to the level of the conductive layer by plasma or wet etching.

Next, the remaining resin is removed (stripped) so as to only leave the structured dielectric layer on the conductive layer.

Growth of the structures by electrochemistry in the thereby formed cavities is accomplished.

The produced patterns will have a height slightly larger than the height of the structures made in the dielectric layer in order to create a topography relative to the dielectric surface.

The OLED layers are then deposited on the obtained nanostructured substrate.

1. A method for manufacturing an electrode for an organic light-emitting diode OLED, said electrode comprising a surface comprising a first dielectric nanostructuration and a second metal nanostructuration, on a substrate, wherein the following successive steps are carried out:
a) a metal layer is deposited on a planar surface of a substrate;
b) on the metal layer, a dielectric layer comprising said first dielectric nanostructuration which includes cavities which extend from the upper surface of the dielectric layer as far as the upper surface of the metal layer, is prepared;
c) the cavities of the first dielectric nanostructuration are at least partially filled with a metal, whereby the second metal nanostructuration is obtained.

2. The method according to claim 1, wherein, during step b), the dielectric layer comprising the first nanostructuration is prepared by depositing a layer in a dielectric material and then a resin layer onto the metal layer, by proceeding with lithography of the resin layer in order to remove the resin in areas corresponding to the cavities to be defined in the dielectric layer, by etching the layer in a dielectric material in order to define the cavities, and by removing the resin.

3. The method according to claim 2, wherein the lithography of the resin layer is carried out by a method selected from optical lithography, electronic lithography, UV-assisted nano-imprinting lithography, and thermal nano-imprinting lithography.

4. The method according to claim 3, wherein the dielectric material is selected from SiO₂, HfO₂, and from all electrically insulating materials.

5. The method according to claim 4, wherein the resin is selected from thermoplastic resins and thermosetting resins such as polystyrenes (PS), polymethyl methacrylates (PMMAs), unsaturated polyesters, epoxy resins, phenolic resins, polyimides, polyamides, polycarbonates, polyolefins such as polypropylenes, POSS or polyhedral oligomeric silsesquioxane, and mixtures thereof.

6. The method according to claim 1, wherein, during step b), the dielectric layer comprising the first nanostructuration is prepared by depositing a layer in a dielectric resin, or a layer in a resin or in a material, said resin or said material being capable of being transformed into a dielectric material, on the metal layer, by proceeding with lithography of the layer in a resin or in a material capable of being transformed into a dielectric material in order to define the cavities therein, and by transforming the resin or the material capable of being transformed into a dielectric material, into a dielectric material, by a heat treatment.

7. The method according to claim 6, wherein the dielectric layer is in a dielectric material selected from materials called spin-on-glass materials or centrifuged glasses.

8. The method according to claim 7, wherein the lithography of the layer in a resin or in a material capable of being transformed into a dielectric material is carried out by a method selected from optical lithography, electronic lithography, UV-assisted nano-imprinting lithography, and thermal nano-imprinting lithography.

9. The method according to claim 8, wherein the substrate is in a material selected from glass, transparent ceramics and transparent plastics.

10. The method according to claim 9, wherein the metal layer is in a metal selected from platinum, cobalt, nickel, iron, silver, aluminium, iridium, gold, molybdenum, palladium; and alloys thereof.

11. The method according to claim 1 wherein step c) is performed by an electrochemical method selected from electrodeposition methods with imposed potential or current and electro-reduction methods without any current called electro-less methods.

12. The method according to claim 1, wherein the cavities of the first nanostructuration of the dielectric layer are filled with a metal, at least up to the upper surface of the dielectric layer.

13. The method according to claim 12, wherein the cavities of the first nanostructuration of the dielectric layer are filled with a metal, beyond the upper surface of the dielectric layer.

14. The method according to claim 13, wherein the metal which juts out beyond the upper surface of the dielectric layer, forms relief patterns with a height from 1 to 100 nm relatively to the level of the upper surface of the dielectric layer.

15. The method according to claim 1, wherein the first nanostructuration is composed of a periodic lattice, such as a one-dimensional lattice or a two-dimensional lattice.

16. The method according to claim 15, wherein the first nanostructuration is a lattice of lines with periodic patterns of period P1 preferably from 100 nm to 1 μm and with a height h1 preferably from 5 nm to 100 nm.

17. The method according to claim 16, wherein the lines of the first nanostructuration have a width from 50 nm to 550 nm.

18. The method according to claim 15, wherein the first nanostructuration is a lattice of pads.

19. The method according to claim 16, wherein the second nanostructuration is a lattice of lines with periodic patterns of period P2 preferably from 100 nm to 1 μm, still preferably from 200 nm to 600 nm, and with a height h2 preferably from 5 nm to 100 nm.

20. The method according to claim 19, wherein the lines of the second nanostructuration have a width from 50 nm to 550 nm.

21. A method for manufacturing an organic light-emitting diode OLED comprising at least one step for manufacturing an electrode, comprising a surface comprising a first dielectric nanostructuration and a second metal nanostructuration, on a substrate, wherein said step is carried out with the method according to claim 1.

22. The method according to claim 21, wherein a first electrode is manufactured, comprising a surface comprising a first dielectric nanostructuration and a second metal nanostructuration, on a substrate, with the method according to claim 1 and then one or more emitting organic layer(s) conforming to the nanostructured surface of the first electrode and a second electrode layer conforming to the nanostructured surface of the first electrode are successively deposited on the nanostructured surface of the first electrode.

23. The method according to claim 22, wherein the first electrode is an anode and the second electrode is a cathode.

24. The method according to claim 22, wherein one or more other layer(s) conforming to the nanostructured surface of the first electrode, selected from a holes injection layer, a holes transport layer, an electrons injection layer, an electrons transport layer, a holes blocking layer, an electrons layer blocking layer, and a thin film transistors (TFT) are further deposited on the first electrode, two or more among this(these) other layer(s), the organic emitting layer(s), the first electrode layer and the second electrode layer being optionally merged.
